(19) United States
(12) Patent Application Publication
(10) Pub. No.: US 2007/0090505 A1
(43) Pub. Date: Apr. 26, 2007

(54) Apparatus and method for manufacturing imaging device package

(75) Inventor: Masato Kikuchi, Kurokawa-gun (JP)

Correspondence Address: SUGHRUE-265550, 2100 PENNSYLVANIA AVE. NW, WASHINGTON, DC, 20037-3213, US

(73) Assignee: FUJIFILM Corporation

(21) Appl. No.: 11/582,959

(22) Filed: Oct. 19, 2006

(30) Foreign Application Priority Data
Oct. 20, 2005 (JP) P 2005-305983

(51) Int. Cl. H01L 23/02

(52) U.S. Cl. 257/680

(57) ABSTRACT

An apparatus for manufacturing a package packing a solid-state imaging device is provided, the package having: a package container fixing the solid-state imaging device therein; and an IR-coated cover glass hermetically sealing the solid-state imaging device in the package container. The apparatus has an ultraviolet radiation unit that radiates an ultraviolet ray to the package in which the IR-coated cover glass are bonded to the package container with an ultraviolet-curing resin, the ultraviolet radiation unit being disposed in a position to radiate the ultraviolet ray in a direction inclining relative to a surface of the cover glass.

### BACKGROUND OF THE INVENTION

1. Field of the Invention

The present invention relates to an apparatus and method for manufacturing an imaging device package hermetically housing an imaging device therein.

2. Description of Related Art

A solid-state imaging apparatus, such as a CCD imaging sensor, usually has an imaging device package housing and fixing therein a solid-state imaging device, such as a CCD chip.

FIG. 7 is a view showing a structure of the usual imaging device package. As shown in FIG. 7, an imaging device package 100 has a package body 101 housing therein a solid-state imaging device 104 fixed on a bottom surface 103a of a recess formed in a package container 103 through a die-bonding agent 108. In the package body 101, inner leads 109 are formed on an upper surface of a step 103b formed in the bottom surface 103a of the recess in a manner being adjacent the periphery of the solid-state imaging device 104. The inner leads 109 are connected to the solid-state imaging device 104 through bonding wires 106. The inner leads 109 are electrically connected to outer leads, not shown. Through the outer leads, the imaging device package is connected on a drive-circuit board on a solid-state-imaging device-apparatus side. The package body 101 is bonded with a transparent seal glass 102 in a manner closing an opening of the package container thus hermetically closing, from the external, the solid-state imaging device housed in a space defined within the package container 103. Here, the seal glass 102 is fixed to the package body 101 with an ultraviolet-curing resin 111.

In the meanwhile, there is a recent proposal that uses an IR-coated glass attached as a seal glass 102 on an optical component (hereinafter, referred to as an IR-blocking filter or IRCF) due to the thickness reduction of a solid-state imaging device 104 (see JP-A-2002-50751, for example). Here, the solid-state imaging device, sensitive to the infrared portion of light, is generally under the specification to block infrared light at around 1,000 nm in order to prevent the occurrence of trouble as caused by such infrared light entered the solid-state imaging device. Meanwhile, IR-blocking filter has a property to block an ultraviolet light at 370 nm or smaller.

Meanwhile, it is the general trend to use a sulfonium salt as a photo-polymerization initiator contained in an ultraviolet-curing resin. However, it is known that the ultraviolet-curing resin having a sulfonium salt is to absorb light in a range of wavelength of from 310 to 380 nm. As shown in FIG. 7, when bonding the IR-blocking filter by the use of such an ultraviolet-curing resin 11, ultraviolet rays are radiated from vertically above of the imaging device package 100 onto a seal glass 102 by an ultraviolet radiation unit 110. Thereupon, the ultraviolet rays, radiated to the seal glass 102, are blocked in its shorter wavelength by the characteristic of the IR-blocking filter. Thus, the ultraviolet-curing resin 111 is not sufficiently cured and hence not properly cured or otherwise long time is required before cured properly. Thus, there is a room for improvement in this respect.

### SUMMARY OF THE INVENTION

An object of an illustrative, non-limiting embodiment of the invention is to provide an apparatus and method for an imaging device package capable of surely curing an ultraviolet-curing resin in a short time when bonding an IR-blocking filter, which blocks ultraviolet rays to a package body, with the ultraviolet-curing resin.

According to one aspect of the invention, there is provided an apparatus for manufacturing an imaging device package (i.e., a package packing a solid-state imaging device) having: a package container fixing the solid-state imaging device therein; and an IR-coated cover glass hermetically sealing the solid-state imaging device in the package container. The apparatus includes an ultraviolet radiation unit that radiates an ultraviolet ray to the package in which the IR-coated cover glass are bonded to the package container with an ultraviolet-curing resin, and the ultraviolet radiation unit is disposed in a position to radiate the ultraviolet ray in a direction inclining relative to a surface of the cover glass.

Meanwhile, according to one aspect of the invention there is provided a method for manufacturing a solid-state imaging device package having: a package container fixing the solid-state imaging device therein; and an IR-coated cover glass hermetically sealing the solid-state imaging device in the package container. The method includes radiating an ultraviolet ray to the package in which the IR-coated cover glass are bonded to the package container with an ultraviolet-curing resin, wherein the ultraviolet ray is radiated in a direction inclining relative to a surface of the cover glass.

It is preferable in one aspect of the invention that the ultraviolet ray is incident upon the surface of the cover glass at an angle of 40 to 50 degrees.

It is preferable that a plurality of the ultraviolet radiation units is disposed around the package container of the imaging device package. This makes it possible to radiate ultraviolet rays more evenly to the ultraviolet-curing resin entirety from the ultraviolet radiation units, thus preventing the occurrence of uneven cure in the ultraviolet resin.

It is preferable that the ultraviolet radiation unit is an ultraviolet fiber. This can arrange the ultraviolet-ray fiber in a position to radiate the ultraviolet ray in a direction inclining relative to the surface of the cover glass. By placing a radiation-end face of the ultraviolet fiber in a state inclining an angle relative to the surface of the cover glass, the ultraviolet ray radiated from the ultraviolet fiber is to be incident, in an inclining direction, upon the surface of the cover glass.

### BRIEF DESCRIPTION OF THE DRAWINGS

The features of the invention will appear more fully upon consideration of the exemplary embodiments of the inventions, which are schematically set forth in the drawings, in which:

FIG. 1 is a plan view showing one exemplary embodiment of an imaging device package;

FIG. 2 is a sectional view of the imaging device package;

FIG. 3 is a view showing a state of, viewing from side, a manufacturing apparatus for an imaging device package according to one aspect of the invention;

FIG. 4 is a view showing a state of, viewing from above, the manufacturing apparatus for an imaging device package according to one aspect of the invention;

FIG. 5 is a graph showing a change of transmittance (%) against a wavelength (nm) of radiation light, based on each of incident angles;

FIG. 6 is a graph showing a relationship between a light transmittance against a broad range of wavelength; and

FIG. 7 is a view explaining a state of radiating ultraviolet rays to an imaging device-package in the related art.

### DETAILED DESCRIPTION OF THE EXEMPLARY EMBODIMENTS

Although the invention will be described below with reference to the exemplary embodiment thereof, the following exemplary embodiment and its modification do not restrict the invention.

One aspect of the invention can provide an apparatus and method for an imaging device package capable of surely curing an ultraviolet-curing resin in a short time when bonding an IR-blocking filter, which blocks ultraviolet rays to a package body, with the ultraviolet-curing resin.

Based on the drawings, descriptions will be made below on an exemplary embodiment according to the present invention.

Description is first made on the structure of an imaging device package manufactured by means of a manufacturing apparatus for an imaging device package according to an exemplary embodiment of the invention.

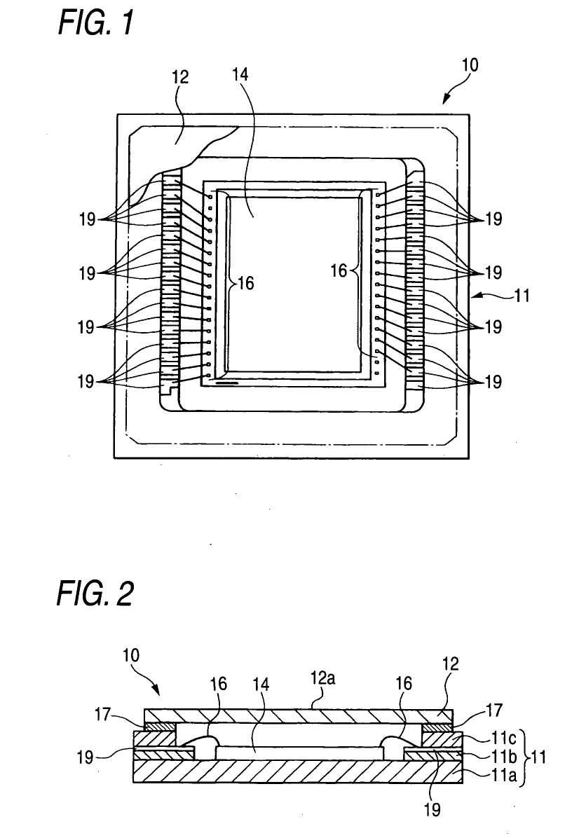

FIG. 1 is a plan view showing an example of an imaging device package manufactured according to an exemplary embodiment of the invention. FIG. 2 is a sectional view of the imaging device package in the present embodiment.

As shown in FIGS. 1 and 2, an imaging device package 10 has a package container 11 generally rectangular in form, in a state viewed from above (viewed from front in FIG. 1). The package container 11 is structured by accumulating, one over another, a plurality (three in the embodiment) of boards 11a, 11b, 11c made of ceramic, resin or the like. The present embodiment has a first board 11a provided as a generally rectangular plate member, on which is bonded a second board 11b equal in outer size to the first board 11a and formed with a generally rectangular opening therein. On the second board 11b, a frame-like third board 11c equal in outer size to the first and second boards 11a, 11b and formed with an opening generally rectangular in form slightly greater in size than the opening of the second board.

The package container 11 has the first board 11a as a bottom plate and the second and third boards 11b, 11c as side plates, thus being structured to house a solid-state imaging device in a space defined by the bottom and side plates. In the imaging device package 10 of this embodiment, a solid-state imaging device 14 is bonded on an upper surface of the first board 11a with a die-bonding agent, not shown.

A plurality of inner leads 19 are formed of a conductive material on the upper surface of the second board 11b for the package container 11. The inner leads 19 are partly exposed in the interior space of the package container 11, in a step between the second and third boards 11b, 11c.

Each of the inner leads 19 are electrically connected with an outer lead, not shown. The outer lead, extending to the outside of the package container 11, serve as a terminal for connecting the imaging device package 10 onto a drive circuit board provided on a solid-state-imaging device apparatus side.

Bonding wires 16 of gold or the like are connected between the solid-state imaging device 14 fixed within the package container 11 and the inner leads 19 formed laterally of the solid-state imaging device 14.

A cover glass 12 is bonded on the upper surface of the third board 11c of the package container 11 with an ultraviolet-curing resin 17. The cover glass 12 is bonded to the package container 11 by being externally exposed to ultraviolet radiation to cure the ultraviolet-curing resin, as referred later. In this manner, in the imaging device package 10, the solid-state imaging device 14 is hermetically housed in the package container 11.

In this embodiment, the cover glass 12 is an IR-blocking filter having, on its surface, an IR coat layer to block infrared light. The IR coat layer is a multi-layer film, say, stacked with alternate SiO₂ and Ta₂O₅ layers. The cover glass 12 has a property to block a ultraviolet ray having a wavelength of approximately 370 nm or smaller.

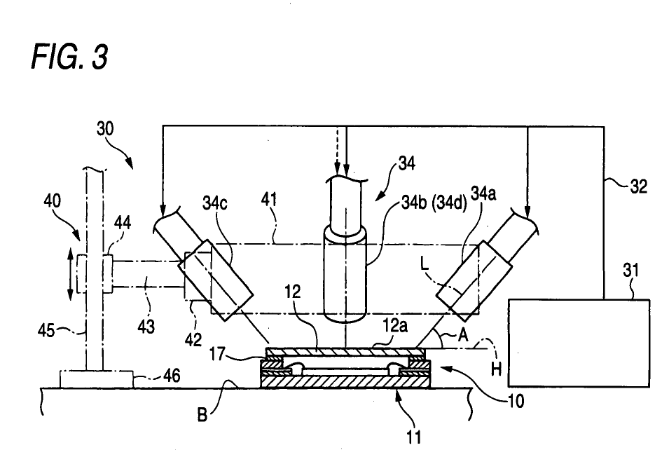

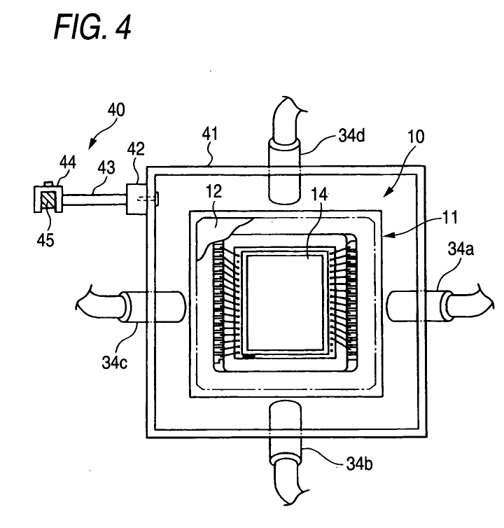

FIG. 3 is a view showing an arrangement of an imaging device package-manufacturing apparatus according to an exemplary embodiment of the invention. FIG. 4 is a view showing a state viewing, from above, the imaging device package according to an exemplary embodiment of the invention.

As shown in FIGS. 3 and 4, the imaging device package-manufacturing apparatus 30 has an ultraviolet radiation unit 34 by which an ultraviolet ray is to be radiated to the imaging device package 10 placed on a support surface. In this embodiment, as the ultraviolet radiation unit 34, four ultraviolet fibers 34a, 34b, 34c, 34d are used. Note that the ultraviolet fibers 34a, 34b, 34c, 34d are not especially limited in the number but preferably provided in plurality surrounding the imaging device package 10.

The ultraviolet fibers 34a, 34b, 34c, 34d are disposed, one by one, in positions above and close to the outer peripheral sides of the imaging device package 10. The ultraviolet fibers 34a, 34b, 34c, 34d are connected to an ultraviolet-ray source 31 through a light guide 32, such as a fiber. Note that ultraviolet-ray sources may be connected independently to the ultraviolet fibers 34a, 34b, 34c, 34d or the same ultraviolet-ray source may be connected to the ultraviolet fibers 34a, 34b, 34c, 34d.

The ultraviolet fibers 34a, 34b, 34c, 34d, in this embodiment, are held in the above of the imaging device package 10 by a support member 40. The support member 40 is not limited in structure to that of the present embodiment.

The support member 40 has a rectangular support frame 41 to support the ultraviolet fibers 34a, 34b, 34c, 34d at their tips to radiate ultraviolet rays. The support frame 41 is formed greater, in top view, than the outer shape of the imaging device package 10. In frame plates corresponding to the sides of the support frame 41, there are formed fiber insertions, such as openings or slits. The ultraviolet fibers 34a, 34b, 34c, 34d are supported in the support frame 41 by being inserted in the respective fiber insertions. In a part of the support member 41, a frame support 42 is provided to connect one end of a movable shaft 43 to the frame support 42. The movable shaft 43 has the other end provided with a slide 44. The slide 44 is attached for vertical movement over a guide rod 45 provided standing nearly vertical to a support surface B. In a lower end of the guide rod 45, a base 46 is provided resting or fixed on the support surface B.

The support member 40 is structured to vertically move the support frame 41, connected through the movable shaft 43, by vertically moving the slide 44 lengthwise of the guide rod 45. By vertically moving the support frame 41 over the support member 40, the ultraviolet fibers 34a, 34b, 34c, 34d held by the support frame 41 can be adjusted in vertical position relative to the imaging device package 10.

In the above imaging device package 10, the ultraviolet radiation unit 34 is disposed in a position where to radiate an ultraviolet ray in a direction inclining relative to a surface 12a of the cover glass 12.

In this embodiment, it is preferable to provide an angle A, in a range of from 40 to 50 degrees, defining between an optical axis L vertical to an ultraviolet-ray radiation end face of the ultraviolet fiber 34a, 34b, 34c, 34d and a direction H parallel with the surface of the cover glass 12. More preferably, it is in a range of from 40 to 45 degrees.

According to the study eagerly, it has been found that, in the case to radiate an ultraviolet ray to an ultraviolet-curing resin 17 of the imaging device package 10 whose cover glass 12 has been bonded with an ultraviolet-curing resin, radiating the ultraviolet ray in an inclining direction to the surface of the cover glass 12 can cause a more sufficient cure of the ultraviolet-curing resin 17 into surely curing, and the time required for curing can be shortened, as compared to the case to radiate a ultraviolet ray vertically to the surface of the cover glass 12 as in the related art. In this embodiment, when the cover glass 12 is bonded to the imaging device package 10 with an ultraviolet-curing resin 17, an ultraviolet ray is radiated from the ultraviolet radiation unit 34 obliquely to the cover glass 12 thereby curing the ultraviolet-curing resin 17. This makes it possible to cure the ultraviolet-curing resin 17 positively and in a short time.

Description is now made on an effect to be provided by the apparatus and method for manufacturing an imaging device package according to an exemplary embodiment of the invention.

A test was conducted to measure the light transmittance against an incident angle by radiating light to a cover glass of an IRCF-treated imaging device package. Incidentally, the imaging device package was the same in structure as the imaging device package 10 of the present embodiment. Here, incident angle refers to an angle of light incidence relative to a surface of the cover glass, which corresponds to angle A if referred to the FIG. 3 structure. In the present measurement, transmittance was measured at an angle of light incidence of 0, 10, 20, 30, 40 and 45 degrees. The incident angle at 0 degree means an angle of light incidence parallel to the surface of the cover glass.

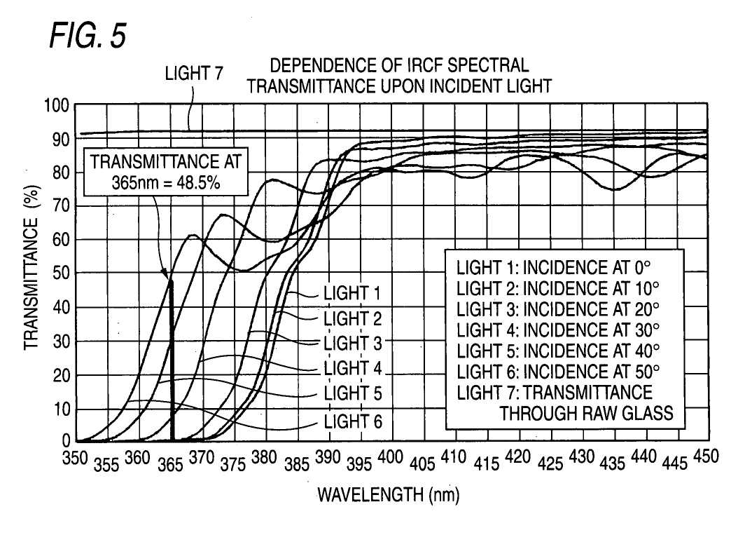

FIG. 5 is a graph showing a change of transmittance (%) against a wavelength (nm) of radiation light, based on each incident angle. As shown by light 5, 6 in FIG. 5, it was found that, where the light incident angle is taken 40 or 45 degrees, transmittance is 30% or greater at a wavelength of 365 mn wherein infrared light are to be fully transmitted. Particularly, when light incident angle is taken 45 degrees, transmittance is 48.5% wherein high transmittance is preferably obtained. It is apparent that the ultraviolet ray is to be fully transmitted. Meanwhile, it was found that the result is not preferable at a light incident angle of 50 degrees or over.

Meanwhile, as shown by light 1, 2, 3, 4 in FIG. 5, transmittance is lower than 10% at a light incident angle of 0, 10, 20 or 30 degrees. It was found that the ultraviolet ray is mostly blocked.

Incidentally, as shown by light 7 in FIG. 5, when light is incident upon a seal glass (so-called a raw glass) not subjected to IRCF processing as seen on the usual ultraviolet-curing means, transmittance is obtained 90% or higher regardless of the wavelength.

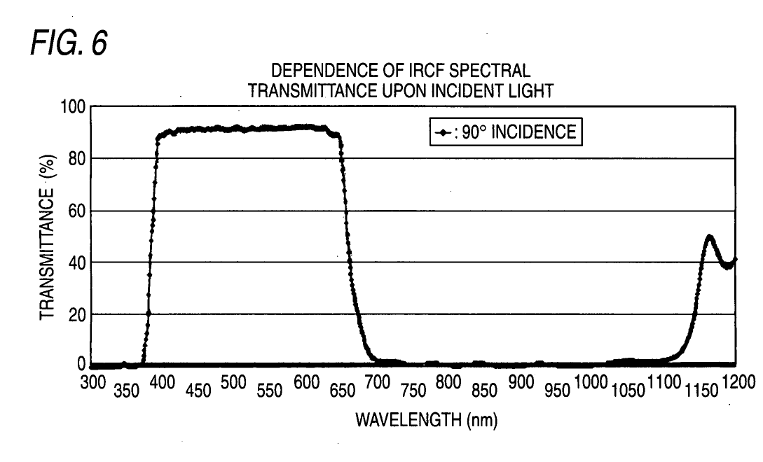

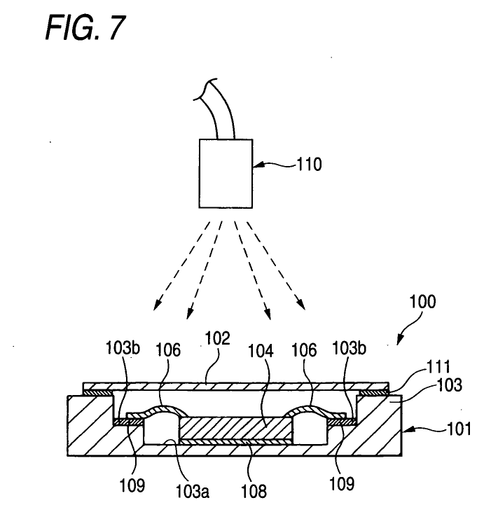

Description is now made on the spectral transmission characteristic through a cover glass IRCF-treated. FIG. 6 is a graph showing a relationship of a light transmittance against a broad range of wavelength. Here, light incident angle was taken as 90 degrees. As shown in FIG. 6, the IRCF-treated cover glass has a characteristic to block light having wavelength ranges of from approximately 370 nm to 700 nm and of approximately 1000 nm.

As described above, when an IRCF-treated cover glass is bonded to the imaging device package with an ultraviolet-curing resin, an ultraviolet ray is preferably radiated at an inclining angle of from 40 to 50 degrees, more preferably 40 to 45 degrees, to a surface of the cover glass. By doing so, the ultraviolet ray is allowed to transmit the cover glass at a high transmittance thus making it possible to sufficiently cure the ultraviolet-curing resin. Meanwhile, because of the capability of radiating an ultraviolet ray to the ultraviolet-curing resin, the time required for cure can be shortened thus providing high efficiency. Therefore, in the apparatus and method for manufacturing an imaging device package according to the present embodiment, ultraviolet-curing resin can be surely cured and in a short time with efficiency by entering an ultraviolet ray to a cover glass at an angle of 40 to 50 degrees relative to the surface of the cover glass.

While the invention has been described with reference to the exemplary embodiments, the technical scope of the invention is not restricted to the description of the exemplary embodiments. It is apparent to the skilled in the art that various changes or improvements can be made. It is apparent from the description of claims that the changed or improved configurations can also be included in the technical scope of the invention.

This application claims foreign priority from Japanese Patent Application No. 2005-305983, filed Oct. 20, 2005, the entire disclosure of which is herein incorporated by reference.

What is claimed is:

1. An apparatus for manufacturing a package packing a solid-state imaging device, the package comprising: a package container fixing the solid-state imaging device therein; and an IR-coated cover glass hermetically sealing the solid-state imaging device in the package container,
the apparatus comprising an ultraviolet radiation unit that radiates an ultraviolet ray to the package in which the IR-coated cover glass are bonded to the package container with an ultraviolet-curing resin, the ultraviolet radiation unit being disposed in a position to radiate the ultraviolet ray in a direction inclining relative to a surface of the cover glass.

2. The apparatus according to claim 1, wherein the ultraviolet ray is incident upon the surface of the cover glass at an angle of 40 to 50 degrees

3. The apparatus according to claim 1, which has a plurality of ultraviolet radiation units disposed around the package container.

4. The apparatus according to claim 1, wherein the ultraviolet radiation unit is an ultraviolet fiber.

5. A method for manufacturing a package packing a solid-state imaging device, the package comprising: a package container fixing the solid-state imaging device therein; and an IR-coated cover glass hermetically sealing the solid-state imaging device in the package container,
the method comprising radiating an ultraviolet ray to the package in which the IR-coated cover glass are bonded to the package container with an ultraviolet-curing resin, wherein the ultraviolet ray is radiated in a direction inclining relative to a surface of the cover glass.

6. The method according to claim 5, wherein the ultraviolet ray is incident upon the surface of the cover glass at an angle of 40 to 50 degrees

7. The method according to claim 5, which has a plurality of ultraviolet radiation units disposed around the package container.

8. The method according to claim 5, wherein the ultraviolet radiation unit is an ultraviolet fiber.
